(19) United States
(12) Patent Application Publication
(10) Pub. No.: US 2009/0201067 A1
(43) Pub. Date: Aug. 13, 2009

(54) REFERENCE VOLTAGE GENERATING CIRCUIT, INTEGRATED CIRCUIT DEVICE, AND SIGNAL PROCESSING APPARATUS

(75) Inventor: Hideo Haneda, Matsumoto-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPORATION, Shinjuku-ku (JP)

(21) Appl. No.: 12/370,487

(22) Filed: Feb. 12, 2009

(30) Foreign Application Priority Data
Feb. 12, 2008 (JP) 2008-030043
Nov. 21, 2008 (JP) 2008-297731

(51) Int. Cl. H03L 5/00; H01L 35/00

(52) U.S. Cl. 327/306; 327/512

(57) ABSTRACT

A reference voltage generating circuit that generates a reference voltage includes: a first pn junction that generates a first voltage; a second pn junction that has a different current density from the first pn junction; a first resistor that generates a first current having a positive temperature coefficient based on a voltage equivalent to a difference between a forward voltage of the first pn junction and a forward voltage of the second pn junction; a second resistor that generates a first voltage having a positive temperature coefficient based on the first current, wherein the first voltage having the positive temperature coefficient and a voltage having a negative temperature coefficient are added to generate the reference voltage; and a third resistor that generates a temperature-dependent voltage based on the first current having the positive temperature coefficient, wherein the reference voltage and the temperature-dependent voltage are outputted in parallel from first and second output nodes, respectively, and a resistance value of the first resistor and a resistance value of the third resistor are adjusted in the same proportion by a trimming signal.

This application claims priority to Japanese Patent Application No. 2008-030043, filed Feb. 12, 2008 and Japanese Patent Application No. 2008-297731, filed Nov. 21, 2008. The entire disclosures of which are expressly incorporated by reference herein.

### BACKGROUND

1. Technical Field

The present invention relates to a reference voltage generating circuit (particularly a reference voltage generating circuit that outputs a reference voltage and a temperature-dependent voltage in parallel), an integrated circuit device, and a signal processing apparatus.

2. Related Art

If an analog signal is handled in an integrated circuit (IC), a reference voltage is required. A reference voltage generating circuit is the circuit that generates this voltage. For example, in the case of amplifying an analog signal by using an OP amplifier (operation amplifier), amplification may be based on a certain reference voltage value. Therefore, if the reference voltage value changes, the analog signal cannot be correctly amplified. As this voltage that serves as a reference, a constant value must be outputted with respect to voltage change in power provided to the integrated circuit from outside and temperature change in the integrated circuit.

A temperature sensor circuit is a circuit that converts temperature to a voltage or current and outputs this voltage or current to provide temperature information. For example, an analog signal may be corrected in accordance with temperature information acquired from the temperature sensor circuit. Analog signals outputted from a sensor that detects the acceleration rate or angular velocity are generally temperature-dependent. These analog signals may be corrected in accordance with temperature information acquired from the temperature sensor circuit in order to eliminate their temperature dependence. Thus, if temperature information outputting constantly the same value is not acquired for the same temperature, the signals cannot be properly corrected. As temperature information, the voltage (or current) outputted with respect to temperature must have highly accurate linearity and the voltage (or current) outputted for a certain temperature must be constant, that is, highly stable.

### Explanation of Reference Voltage Generating Circuit

For a reference voltage generating circuit, a band gap reference circuit (hereinafter referred to as BGR circuit) is typically used. An exemplary BGR circuit may have a configuration as shown in FIG. 1 (see, for example, JP-A-2003-258105). In FIG. 1, A₁ represents an operational amplifier, R₁, R₂ and R₃ represent resistors, and Q₁ and Q₂ represent pnp-type bipolar transistors (hereinafter referred to as BJT). The symbol n represents a natural number, indicating that n BJTs are connected in parallel. The BJT parts may be replaced by diodes. V_{ref} represents reference voltage output (constant-voltage output).

In the BJTs having a short circuit between the base (B) and the collector (C), like Q₁ and Q₂ in FIG. 1, if temperature rises in the state where the current flowing from the emitter (E) is kept constant, the voltage V_{EB} between the base (B) and the emitter (E) is reduced. The characteristic of reducing voltage with respect to temperature rise is called a “negative temperature characteristic”. Q₁ and Q₂ in FIG. 1 are elements having the negative temperature characteristic.

Meanwhile, since the input terminals (PIN, NIN) of the operational amplifier A₁ are virtually short-circuited, these input terminals have the same potential. That is, since the same voltage is applied to both ends of each of the resistors R₁ and R₂, the ratio of the currents flowing through R₁ and R₂ is kept constant. Since these currents flow into the BJTS, the ratio of the currents flowing into the BJTs of Q₁ and Q₂ is kept constant as well. It can be understood that as different currents at a constant ratio are caused to flow into the two BJTS, respectively, the potential difference V_{EB1}-V_{EB2} between the voltages V_{EB1} and V_{EB2}, between the base (B) and the emitter (E) of the respective BJTs of Q₁ and Q₂ corresponds to the voltage applied to both ends of the resistor R₃ in consideration of the fact that the input terminals of the operational amplifier A₁ are virtually short-circuited. This voltage difference increases if temperature rises. This characteristic of increasing voltage with respect to temperature rise is called a “positive temperature characteristic”. It can be understood that the resistor R₃ behaves as if it had a positive temperature characteristic.

Since the same current flows through R₂ and R₃ and the ratio of the currents flowing through R₁ and R₂ is kept constant, it can be seen that the voltage applied to both ends of each of R₁ and R₂ changes as well corresponding to R₃. Thus, it can be understood that R₁ and R₂, too, behave to have a positive temperature characteristic.

In FIG. 1, the output V_{ref} of the BGR circuit is the sum of the voltage V_{EB} between the base (B) and the emitter (E) of the BJTs and the voltage applied to both ends of the resistors. As described so far, these voltages are the voltage having a negative temperature characteristic and the voltage having a positive temperature characteristic. The output V_{ref} of the BGR circuit is the sum of these voltages. FIG. 2 shows its outline. As these voltages having positive and negative temperature characteristics are added in an appropriate proportion, a voltage V_{ref} that is not dependent on temperature change is generated.

However, even if the voltages having positive and negative temperature characteristics are added in an appropriate proportion, the temperature characteristic cannot be completely eliminated from V_{ref}. As shown in FIG. 3, the temperature dependence of V_{ref} is generally expressed as a curve that is approximate to a quadric function having an apex at a certain temperature. This BGR circuit is designed in such a manner that the temperature dependence curve of V_{ref} has an apex around room temperature. The problem in this design is variation in elements. When elements such as resistors are formed on an integrated circuit, variation arises in the elements. Generally, a resistor may have a variation of approximately tens of percentage points from the designed value. However, variation between elements arranged closely to each other on the IC can be restrained to a small extent. That is, in the case of a resistor, the resistance value, which is an absolute value, is substantially different from the designed value, whereas the value of resistance ratio, which is relative value, can be made coincident with the designed value. In view of this, when designing a circuit on an integrated circuit, a design in which only a relative value has influence on the output is employed, avoiding a design in which an absolute value directly influences the output. However, the apex temperature of the temperature dependence curve of V_{ref} in this BGR circuit is directly influenced by the absolute value of the resistor. Since the absolute value of the resistor is substantially different from the designed value, this causes “apex temperature variation” shown in FIG. 3. At the same time, “output voltage variation” occurs as well. Therefore, in the BGR circuit, the circuit needs to be adjusted in accordance with the variation of elements. In the case of the BGR circuit shown in FIG. 1, the absolute value of the resistance value of R₃ directly influences change in the output V_{ref}. Thus, fine adjustment of the resistance value of R₃ is enabled in advance, then the actual quantity of change is examined and the resistance value is adjusted in accordance with the quantity of change. As a result of this adjustment, a V_{ref} characteristic having neither “apex temperature variation” nor “output voltage variation” can be provided.

### Explanation of Temperature Sensor Circuit

The temperature sensor circuit is a circuit that generates a linearly changing voltage or current with respect to temperature change. As a typical example, a configuration as shown in FIG. 4 is used (see, for example, JP-A-2004-310444). A₁ represents an operational amplifier. R₂ and R₃ represent resistors. Q₁ and Q₂ represent pnp-type BJTs. M₁, M₂ and M₃ represent p-type MOS-FETs. V_{PTAT} represents temperature sensor output. V_{DD} represents power-supply voltage supplied to the circuit from outside.

This circuit is very similar to the BGR circuit in terms of operation. As in a typical reference voltage generating circuit, the voltage applied to both ends of the resistor R₃ behaves to have a positive temperature characteristic. That is, the current flowing through the resistor R₃ has a positive temperature characteristic and increases with temperature rise. This current is copied via a current mirror circuit formed by the transistors of M₁, M₂ and M₃, and a current having a positive temperature characteristic flows into the resistor R₄. Consequently, a voltage having a positive temperature characteristic appears at V_{PTAT}. In this way, the temperature sensor circuit is configured to convert temperature information to V_{PTAT}. FIG. 5 shows the temperature characteristic of V_{PTAT}. Meanwhile, unlike the output V_{ref} of the BGR circuit, the output V_{PTAT} of this circuit has its characteristic decided only by the relative value of the resistor and not directly influenced by the absolute value. Thus, in the case of the temperature sensor circuit, “inclination variation” and “output voltage variation” have little change even if no adjustment is made with respect to element variation.

As can be seen from FIG. 1 and FIG. 4, the reference voltage generating circuit and the temperature sensor circuit have similar circuit configurations. In view of this, the inventor of the present invention considers combining the two circuits to form a single circuit. FIG. 6 shows an example in which the reference voltage generating circuit and the temperature sensor circuit are combined to form a single circuit. A₁ represents an operational amplifier. R₁, R₂, R₃ and R₄ represent resistors. Q₁ and Q₂ represent pnp-type BJTs. M₃ and M₄ represent p-type MOS-FETs. V_{ref} represents constant-voltage output. V_{PTAT} represents temperature sensor output. V_{DD} represents power-supply voltage supplied to the circuit from outside. This circuit has the functions of the reference voltage generating circuit and the temperature sensor circuit and can significantly save the occupied area than when each of these circuits is separately configured on the IC.

The problem to be considered here is adjustment with respect to element variation. As is described so far, the “apex temperature variation” and “output voltage variation” of the output V_{ref} of the BGR circuit are influenced by the absolute value of the resistor and adjustment is necessary with respect to element variation. However, no such adjustment is necessary for the “inclination variation” and “output voltage variation” of the output V_{PTAT} of the temperature sensor circuit. Here, it is assumed that, in order to adjust change in V_{ref}, fine adjustment of the resistance value of R₃ is enabled in advance, then the actual quantity of change is examined and adjustment is made in accordance with the quantity of change, as described above. As a matter of course, since the resistance value of R₃ is adjusted, the resistance ratio, which is a relative value, is changed as well. The change in V_{PTAT} is not influenced by the absolute value of the resistor but is influenced by the relative value. Therefore, the adjustment of the resistance value of R₃ has influence on the change in V_{PTAT}.

In this manner, the circuit shown in FIG. 6 has a problem that the change in only one of V_{ref} and V_{PTAT} node, that is, only the “apex temperature variation” and “output voltage variation” of V_{ref} or the “inclination variation” and “output voltage variation” of V_{PTAT}, can be restrained.

### SUMMARY

According to some embodiments of the invention, for example, in a circuit configuration formed by a combination of a reference voltage generating circuit and a temperature sensor circuit, when making fine adjustment of the resistance value of an appropriate resistor in the circuit in order to restrain “apex temperature variation” and “output voltage variation” of V_{ref} due to element variation, fine adjustment of the resistance value of an appropriate resistor on the temperature sensor circuit side is made simultaneously in the same proportion. Thus, both changes, that is, “apex temperature variation” and “output voltage variation” of V_{ref} and “inclination variation” and “output voltage variation” of V_{PTAT}, can be restrained.

According to an aspect of the invention, a reference voltage generating circuit that generates a reference voltage includes: a first pn junction that generates a first voltage; a second pn junction that has a different current density from the first pn junction; a first resistor that generates a first current having a positive temperature coefficient based on a voltage equivalent to a difference between a forward voltage of the first pn junction and a forward voltage of the second pn junction; a second resistor that generates a first voltage having a positive temperature coefficient based on the first current, wherein the first voltage having the positive temperature coefficient and a voltage having a negative temperature coefficient are added to generate the reference voltage; and a third resistor that generates a temperature-dependent voltage based on the first current having the positive temperature coefficient, wherein the reference voltage and the temperature-dependent voltage are outputted in parallel from first and second output nodes, respectively, and a resistance value of the first resistor and a resistance value of the third resistor are adjusted in the same proportion by a trimming signal.

In the circuit configuration formed by the combination of the reference voltage generating circuit and the temperature sensor circuit, when making fine adjustment of the resistance value of the first resistor in the circuit in order to restrain “apex temperature variation” and “output voltage variation” of the reference voltage due to element variation, fine adjustment of the resistance value of the third resistor on the temperature sensor circuit side is made simultaneously in the same proportion. The resistance values of the first and third resistors can be accurately and finely adjusted electrically by the trimming signal. Moreover, the resistance values of the first and third resistors are adjusted in the same proportion. Thus, both changes, that is, “apex temperature variation” and “output voltage variation” of the reference voltage and “inclination variation” and “output voltage variation” of the temperature sensor output, can be restrained. The generated highly accurate reference voltage can be used, for example, as various reference voltages in an electronic circuit or as a DC bias voltage in a signal line. The temperature sensor output can be used, for example, to generate a temperature compensation signal. By using both the reference voltage and the temperature sensor output, it is possible to generate a constant current having very little dependence on temperature (that is, a constant current that is not dependent on temperature).

It is preferable that the first resistor and the third resistor include a variable resistance circuit in which the first and third resistors have their respective resistance values adjusted in the same proportion in accordance with the trimming signal that is common.

The first resistor and the third resistor include the variable resistance circuit and the variable resistance circuit is controlled by the common trimming signal. As the resistance values of the two resistors are made adjustable in the same proportion by the common trimming signal, the circuit required for adjustment of resistance values can be shared and the circuit area can be reduced. Moreover, since the reference voltage generating circuit and the temperature sensor circuit can be adjusted simultaneously, the adjustment cost can be reduced, compared to the case of separately adjusting each circuit.

It is also preferable that the variable resistance circuit includes: a first ladder resistance circuit including first to m-th (m being an integer equal to 2 or greater) voltage divider-resistors connected in series between a first node and a second node for variably adjusting the resistance value of the first resistor; a second ladder resistance circuit including first to m-th voltage divider-resistors connected in series between a third node and a fourth node for variably adjusting the resistance value of the third resistor; first to i-th bypass switches for the first ladder resistance for switching electric connection and disconnection between each of first to i-th (i being an integer equal to 2 or greater) division nodes and the second node in the first ladder resistance circuit; and first to i-th bypass switches for the second ladder resistance for switching electric connection and disconnection between each of first to i-th (i being an integer equal to 2 or greater) division nodes and the fourth node in the second ladder resistance circuit. A ratio of a resistance value of an n-th voltage divider-resistor (1≦n≦m) forming the first ladder resistance circuit to a resistance value of an n-th voltage divider-resistor (1≦n≦m) forming the second ladder resistance circuit is constant. On-off state of a k-th bypass switch (1≦k≦i) for the first ladder resistance circuit and on-off state of a k-th bypass switch (1≦k≦i) for the second ladder resistance circuit are controlled by the common trimming signal.

An exemplary configuration of the variable resistance circuit is clarified. The bypass switch is provided for bypassing each of the voltage divider node and a predetermined potential point in the first and second ladder resistance circuits. On-off state of the corresponding bypass switch in the first and second ladder resistance is controlled by the common trimming signal. When the bypass switch is turned on, the voltage divider-resistor that is downstream of that bypass switch is invalidated. Only one bypass switch is turned on, and as the bypass switch to be turned on is selected, the resistance value can be finely adjusted. Since the ratio of the resistance values of the corresponding voltage divider-resistors in the first and second ladder resistance is constant, if the resistance value of the voltage divider-resistor forming the first ladder resistance circuit is increased or decreased, the resistance value of the corresponding voltage divider-resistor forming the second ladder resistance circuit is automatically increased or decreased in the same proportion. Thus, both the generation of a highly accurate reference voltage having very little dependence on temperature (that is, a reference voltage that is not dependent on temperature) and a highly accurate temperature sensor output voltage can be realized.

It is also preferable that the variable resistance circuit includes: a first ladder resistance circuit including first to m-th (m being an integer equal to 2 or greater) voltage divider-resistors connected in series between a first node and a second node for variably adjusting the resistance value of the first resistor; a second ladder resistance circuit including first to m-th voltage divider-resistors connected in series between a third node and a fourth node for variably adjusting the resistance value of the third resistor; first to m-th bypass switches for the first ladder resistance circuit provided corresponding to each of the first to m-th voltage divider-resistors forming the first ladder resistance circuit and for bypassing both ends of each of the first to m-th voltage divider-resistors; and first to m-th bypass switches for the second ladder resistance circuit provided corresponding to each of the first to m-th voltage divider-resistors forming the second ladder resistance circuit and for bypassing both ends of each of the first to m-th voltage divider-resistors. A ratio of a resistance value of an n-th voltage divider-resistor (1≦n≦m) forming the first ladder resistance circuit to a resistance value of an n-th voltage divider-resistor (1≦n≦m) forming the second ladder resistance circuit is constant. On-off state of a p-th bypass switch (1≦p≦m) for the first ladder resistance circuit and on-off state of a p-th bypass switch (1≦p≦m) for the second ladder resistance circuit are controlled by the common trimming signal.

Another exemplary configuration of the variable resistance circuit is clarified. According to this configuration, a bypass switch is provided corresponding to each voltage divider-resistor. When one of the bypass switches is turned on, both ends of the corresponding voltage divider-resistor are bypassed and its voltage divider-resistor is invalidated. In this configuration, there are 2n patterns of on-off state of the bypass switch. Therefore, the resistance values of the first and third resistors can be adjusted more finely.

It is also preferable that a potential adjustment resistor for adjusting potential of a node on the fourth node side, of the m-th voltage divider-resistor in the second ladder resistance circuit, is provided between the m-th voltage divider-resistor and the fourth node.

For example, the case of forming the bypass switches by using transistors (for example, MOS transistors) is considered. To improve the accuracy of the ratio of the first resistor and the second resistor, it is desirable that on-resistance of the bypass switch for the first ladder resistance circuit and on-resistance of the bypass switch for the second ladder resistance circuit are made equal. To this end, the source potentials of the two MOS transistors forming the bypass switches need to be the same. To adjust these source potentials, for example, a resistor for adjusting potential of a node on the fourth node side, of the m-th voltage divider-resistor, is provided in the second ladder resistance circuit. As the voltage between both ends of the resistor for potential adjustment is finely adjusted, the source potential of the bypass switch (MOS transistor) on the second ladder resistance circuit side can be finely adjusted. The common trimming signal is applied to the gate of each MOS transistor, and if the source potentials of the respective MOS transistors are the same, the MOS transistors have the same on-resistance. In short, in the first and second ladder resistance circuits, on-resistance of the corresponding bypass switches becomes equal and the accuracy of the ratio of the first resistor and the second resistor is improved.

It is also preferable that the variable resistance circuit includes: first to q-th (q being an integer equal to 2 or greater) resistors for adjustment of the first resistor, connected parallel to each other between the first node and the second node and having their one ends connected in common, for variably adjusting the resistance value of the first resistor; first to q-th resistors for adjustment of the third resistor, connected parallel to each other between the third node and the fourth node and having their one ends connected in common, for variably adjusting the resistance value of the third resistor; first to q-th switch circuits for adjustment of the first resistor, provided corresponding to each of the first to q-th resistors for adjustment of the first resistor, for switching electric connection and disconnection between the other end of each of the first to q-th resistors for adjustment of the first resistor and the second node; and first to q-th switch circuits for adjustment of the third resistor, provided corresponding to each of the first to q-th resistors for adjustment of the third resistor, for switching electric connection and disconnection between the other end of each of the first to q-th resistors for adjustment of the third resistor and the fourth node. A resistance ratio of a resistance value of an r-th (1≦r≦q) resistor for adjustment of the first resistor to a resistance value of an r-th (1≦r≦q) resistor for adjustment of the third resistor is constant. On-off state of an x-th switch circuit (1≦x≦q) for adjustment of the first resistor and on-off state of an x-th switch circuit (1≦x≦q) for adjustment of the third resistor are controlled by the common trimming signal.

This clarifies still another embodiment of the variable resistance circuit. According to this embodiment, whether the first to q-th resistors connected in parallel should be made valid or invalid is selected in accordance with the on-off state of the switch circuit corresponding to each resistor.

It is also preferable that one ends of the first to q-th switch circuits for adjustment of the third resistor are connected to the other ends of the first to q-th resistors for adjustment of the first resistor. At the same time, the other ends of the first to q-th switch circuits for adjustment of the third resistor are connected in common, and a potential adjustment resistor for adjusting potential of each common connection point of the first to q-th switch circuits for adjustment of the third resistor is provided between each common connection point of the first to q-th switch circuits and the fourth node.

As in the previous embodiment, the resistor for potential adjustment is provided so that on-resistance of the corresponding switch circuit can be set similarly.

According to another aspect of the invention, an integrated circuit device includes the above reference voltage generating circuit and a trimming circuit that outputs the trimming signal.

As the trimming circuit is provided within the integrated circuit device (IC), electrical trimming of the reference voltage circuit having the temperature sensor output can be easily carried out. The trimming circuit includes, for example, a ROM containing an adjustment table. In this case, it is possible to carry out efficient resistance trimming using a lookup table system.

In this way, according to some aspects of the invention, in the reference voltage circuit having the temperature sensor output, for example, both changes of “apex temperature variation” and “output voltage variation” of the reference voltage and “inclination variation” and “output voltage variation” of the temperature sensor output can be restrained.

According to still another aspect of the invention, a signal processing apparatus has an analog front end that includes any of the above reference voltage generating circuit and carries out analog signal processing to an analog signal that is inputted thereto, and a signal processing unit that executes predetermined signal processing based on an output signal of the analog front end.

According to this aspect, the analog front end (AFE) for analog signal processing is provided with any of the above reference voltage generating circuit. The reference voltage generating circuit can be used as a reference voltage source or a power voltage source for at least one circuit included in the analog front end (AFE). Moreover, since the reference voltage generating circuit can output a temperature-dependent voltage, the reference voltage generating circuit can also function as a temperature sensor to measure ambient temperature around the analog front end (AFE). It is also possible to carry out temperature characteristic correction to correct the temperature characteristic of the circuit in accordance with the temperature-dependent signal.

After the analog front end (AFE), the signal processing unit (for example, a digital signal processor, i.e., DSP) is provided. The analog front end (AFE) and the signal processing unit constitute the signal processing apparatus (for example, an analog signal processing apparatus). Since the circuit characteristic of the analog front end (AFE) is stable with respect to temperature, the signal processing apparatus can execute highly accurate signal processing without being influenced by temperature.

It is preferable that the analog front end has an analog-digital (A/D) converter that converts an analog signal to a digital signal. The reference voltage outputted from the reference voltage generating circuit is supplied to the A/D converter. The temperature-dependent voltage outputted from the reference voltage generating circuit is converted to a digital signal by the A/D converter. The digital signal after the conversion is inputted to the signal processing unit.

According to this embodiment, for example, the A/D converter is provided in the output stage of the analog front end (AFE), and the reference voltage generated by the reference voltage generating circuit is supplied to the A/D converter. The reference voltage generating circuit can be used, for example, as a reference voltage source or a power voltage source of the A/D converter. Since the characteristic of the A/D converter is stable with respect to temperature, constantly accurate A/D conversion can be realized without being influenced by temperature.

It is also preferable that the analog front end has at least one of a filter circuit and a gain adjusting circuit before the A/D converter, and a sensor signal outputted from a sensor is inputted to the analog front end. The signal processing unit has a temperature signal processing unit that execute temperature signal processing based on the temperature-dependent voltage as the digital signal, outputted from the A/D converter.

According to this embodiment, at least one of the filter circuit and the gain adjusting circuit is provided before the A/D converter in the analog front end (AFE). The filter circuit may include, for example, at least one of low-pass filter (LPF), high-pass filter (HPF) and band-pass filter (BPF). The gain adjusting circuit may include, for example, a gain control amplifier. A gain adjustment signal of the gain control amplifier can be generated, for example, by the signal processing apparatus.

Moreover, according to this embodiment, a sensor signal from the sensor (a physical quantity signal, for example, an angular velocity signal from a gyro sensor) is inputted to the analog front end (AFE). Also, according to this embodiment, the signal processing apparatus (for example, DSP) is provided with the temperature signal processing unit that executes temperature signal processing based on the temperature-dependent voltage as the digital signal. For example, a temperature correction signal (temperature compensation signal) is generated by the temperature signal processing unit, and the temperature correction signal (temperature compensation signal) is returned to the sensor. Thus, the temperature characteristic of the sensor can be controlled. Moreover, it is possible to notify the user of ambient temperature (for example, showing temperature on a display panel or the like) in accordance with the signal acquired from the temperature signal processing unit. According to this embodiment, a sensor signal processing apparatus (sensor signal processing system) capable of carrying out constantly stable processing and highly accurate processing without being influenced by ambient temperature can be realized.

### BRIEF DESCRIPTION OF THE DRAWINGS

The invention will be described with reference to the accompanying drawings, wherein like numbers reference like elements.

FIG. 1 is a circuit diagram showing an exemplary configuration of a reference voltage circuit.

FIG. 2 shows characteristics of reference voltage.

FIG. 3 illustrates variation in reference voltage.

FIG. 4 is a circuit diagram showing an exemplary temperature sensor circuit.

FIG. 5 shows temperature characteristics of temperature sensor output.

FIG. 6 is a circuit diagram showing an example in which a reference voltage generating circuit and a temperature sensor circuit are combined to form a single circuit.

FIG. 7A and FIG. 7B are circuit diagrams showing an exemplary configuration of a reference voltage generating circuit according to an embodiment of the invention (a reference voltage generating circuit having a temperature sensor output).

FIG. 8 is a circuit diagram showing another exemplary circuit configuration of a reference voltage generating circuit having a temperature sensor output (V_{PTAT}).

FIG. 9 shows a fundamental configuration of a variable resistance circuit for variably adjusting first and third resistors in an interlocked manner (an example of varying with a common trimming signal).

FIG. 10 is a circuit diagram for explaining the position where a variable resistance circuit is provided.

FIG. 11A and FIG. 11B are circuit diagrams showing an exemplary configuration of a variable resistance circuit.

FIG. 12A and FIG. 12B are circuit diagrams showing another exemplary configuration of a variable resistance circuit.

FIG. 13A and FIG. 13B are circuit diagrams showing still another exemplary configuration of a variable resistance circuit.

FIG. 14 shows still another exemplary circuit configuration of a variable resistance circuit.

FIG. 15 shows an exemplary circuit in the case of generating a constant current having very little dependence on temperature.

FIG. 16 shows an exemplary configuration of a signal processing apparatus that uses the reference voltage generating circuit of an embodiment of the invention.

### DESCRIPTION OF EXEMPLARY EMBODIMENTS

Embodiments of the invention will now be described with reference to the drawings. The following embodiments should not limit the contents of the invention described in claims and all the configurations described in the embodiments are not necessarily essential as measures to realize the invention.

### First Embodiment

First, an example of a basic circuit configuration will be described.

### Example of Basic Circuit Configuration

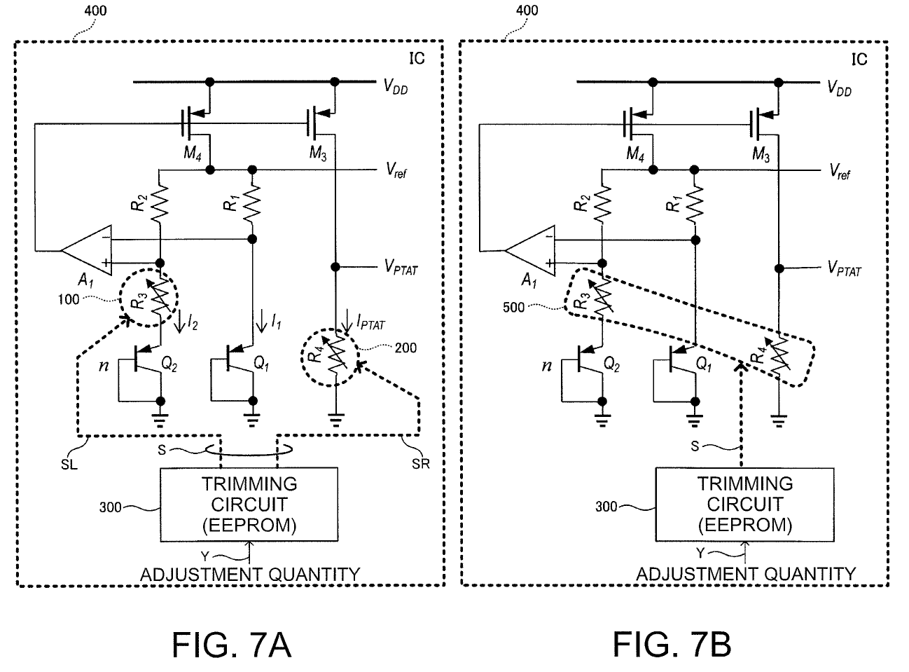

FIG. 7A and FIG. 7B are circuit diagrams showing an exemplary configuration of a reference voltage generating circuit according to the embodiment (a reference voltage generating circuit having a temperature sensor output). Its basic circuit configuration is similar to the circuit configuration shown in FIG. 6. That is, a pnp-type BJT Q₂ is formed, for example, by connecting n BJTs of the same size as a pnp-type BJT Q₁ in parallel. If the pnp-type BJT Q₁ is a single BJT, the pn junction area of the pnp-type BJT Q₂ is n times larger than the pnp-type BJT Q₁. A current flowing through the pnp-type BJT Q₁ is represented by I₁. A current flowing through the pnp-type BJT Q₂ is represented by I₂. If I₁=I₂ holds, the current density of the pnp-type BJTs Q₂ and Q₁ is expressed by 1:n. In the following description, a “resistor R₃” is referred to as a first resistor, a “resistor R₂” is referred to as a second resistor, and a “resistor R₄” is referred to as a third resistor.

The first resistor R₃ is a resistor that generates a current I₂ having a positive temperature coefficient based on a voltage equivalent to the difference in forward voltage between the pnp-type BJTs Q₁ and Q₂ biased with different current densities. The second resistor R₂ generates a voltage having a positive temperature coefficient based on the current I₂ having the positive temperature coefficient. As the voltage (having the positive temperature coefficient) between both ends of the resistor R₂ is added to the forward voltage of the pn junction diode Q₁ having a negative temperature coefficient, a reference voltage (V_{ref}) is generated. It can be said that this reference voltage (V_{ref}) is a reference voltage that has very little change according to temperature and therefore is not dependent on temperature.

The current I₂ having the positive temperature coefficient is copied by a current mirror including MOS transistors M₃ and M₄. A current I_{PTAT} having a positive temperature coefficient is thus acquired. The current I_{PTAT} having the positive temperature coefficient is converted to a voltage by the third resistor R₄. Thus, a voltage (temperature sensor output) V_{PTAT} increasing and decreasing in proportion to temperature is acquired.

However, in the case of FIG. 7A and FIG. 7B, the first resistor R₃, which plays an important role in generating the reference voltage (V_{ref}), and the third resistor R₄ for generating the temperature sensor output are formed by variable resistance circuits. In FIG. 7A, the first resistor R₃ and the third resistor R₄ are formed by separate variable resistance circuits 100 and 200. In FIG. 7B, the first resistor R₃ and the third resistor R₄ are formed by an integrated variable resistance circuit 500.

In the variable resistance circuit (100, 200 or 500), the resistance values of the first resistor R₃ and the third resistor R₄ are adjusted in an interlocked manner in accordance with a trimming signal S from a trimming circuit 300. That is, the resistance values are simultaneously adjusted so that the ratio of the resistance values of the first resistor R₃ and the third resistor R₄ becomes constant.

The reference voltage generating circuit having the temperature sensor output (V_{PTAT}) is loaded on an IC 400. The trimming circuit 300, too, is loaded on the IC 400. As the trimming circuit 300 is provided in the IC 400, electrical trimming of the reference voltage generating circuit having the temperature sensor output can be easily carried out. The trimming circuit 300 includes, for example, a ROM (for example, EEPROM) containing an adjustment table. For example, an adjustment quantity signal Y is inputted to the trimming circuit 300 from outside. If the trimming signal S is generated by using a lookup table system, efficient resistance trimming is possible.

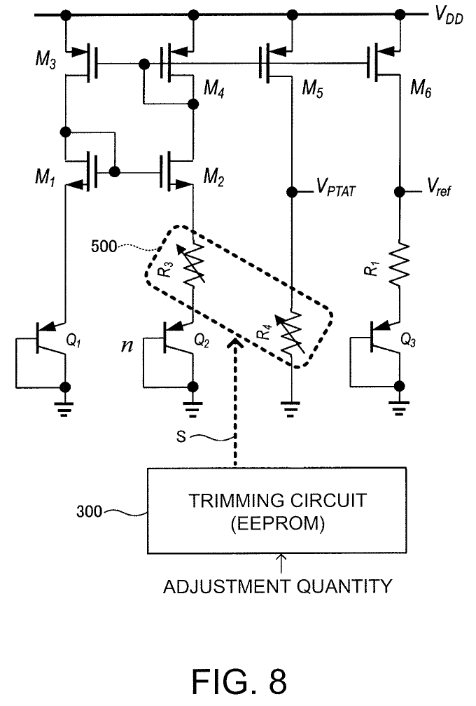

FIG. 8 is a circuit diagram showing another exemplary circuit configuration of the reference voltage generating circuit having the temperature sensor output (V_{PTAT}). The operational amplifier A₁ is used in FIG. 7A and FIG. 7B, whereas in FIG. 8, a current mirror including MOS transistors M₁ to M₄ is used instead of the operational amplifier. In the case of FIG. 8, the junction area of the pn junction diode Q₂ is n times greater than the junction area of the pn junction diode Q₁. If the current mirror ratio of the current mirror including the MOS transistors M₁ to M₄ is 1:1, the total quantity of current flowing through the pn junction diodes Q₁ and Q₂ is the same.

As in the case of using the operational amplifier A₁, the first resistor R₃ is a resistor that generates a current having a positive temperature coefficient based on a voltage equivalent to the difference in forward voltage between the pn junction diodes Q₁ and Q₂. In the case of FIG. 8, the resistor R₁ serves as the second resistor. That is, the resistor R₁ converts a current having a positive temperature coefficient to generate a voltage having a positive temperature coefficient. As the voltage between both ends of the second resistor R₁ having the positive temperature coefficient is added to the forward voltage of the pn junction diode Q₃ having a negative temperature coefficient, a reference voltage (V_{ref}) is generated. Moreover, as a current having a positive temperature coefficient is converted to a voltage by the third resistor R₄, a voltage (temperature sensor output) V_{PTAT} that increases and decreases in proportion to temperature is acquired.

In the circuit shown in FIG. 8, as in FIG. 7B, the first resistor R₃ and the third resistor R₄ are formed by the integrated variable resistance circuit 500. As in FIG. 7A, the first resistor R₃ and the third resistor R₄ may also be formed by separate variable resistance circuits. In any case, the resistance values of the first resistor R₃ and the third resistor R₄ are adjusted in an interlocked manner by the trimming signal S so that the ratio of these resistance values is kept constant.

Before explaining the specific configuration of the variable resistance circuit (100, 200 or 500) and the trimming operation, the reason why trimming of the resistance value of the first resistor R₃ is important for improvement in accuracy of the reference voltage V_{ref} will be explained. Meanwhile, in the case of using the temperature sensor circuit alone, trimming of the third resistor R₄ as in the case of the reference voltage generating circuit is not necessary. The reason for this will explained as well. If the temperature sensor circuit and the reference voltage generating circuit are combined, the influence of resistance trimming on the reference voltage generating circuit also influences the temperature sensor circuit, causing variation in the temperature sensor output. Thus, in this embodiment, the first resistor R₃ and the third resistor R₄ are adjusted in the same proportion in an interlocked manner. By doing so, high accuracy of the outputs of the two circuits can be maintained.

### Reason why Trimming of First Resistor R₃ is Necessary in Reference Voltage Generation

The circuit shown in FIG. 7A will now be referred to. In the case of a band gap reference circuit (BGR circuit), the absolute value of the resistance value of R₃ directly influences change in the output V_{ref}. Here, voltages V_{EB1} and V_{EB2} between the base (B) and the emitter (E) of the BJTs Q₁ and Q₂ are expressed as in the following equations (1) and (2).

$$\begin{matrix}{V}_{EB 1 } = \frac{kT}{q} ln ( \frac{{I}_{1}}{{bT}^{5 / 2} {e}^{- Eg / kT}} ) & ( 1 ) \\ {V}_{EB 2 } = \frac{kT}{q} ln ( \frac{{I}_{2}}{{nbT}^{5 / 2} {e}^{- Eg / kT}} ) & ( 2 )\end{matrix}$$

Here, k represents the Boltzmann constant, T represents absolute temperature, q represents elementary electric charge, b represents a constant related to a BJT that is not dependent on temperature, and Eg represents energy gap. The relation between the base (B)—emitter (E) voltage V_{EB} and the collector current Ic of the BJT is expressed by the following equation (3).

$${I}_{c} = b \cdot {T}^{5 / 2} exp ( \frac{{qV}_{EB} - Eg}{kT} ) \qquad ( 3 )$$

Here, mR₁=R₂ is assumed for convenience. From the relation between the resistance values R₁ and R₂ and the currents I₁ and I₂, the following equation (4) is drawn out.

$${I}_{1} = \frac{{R}_{2}}{{R}_{1}} {I}_{2} = {mI}_{2} \qquad ( 4 )$$

If the input terminals NIN and PIN of the operational amplifier have the same potential, the following equation (5) is drawn out.

V_{EB1}=V_{EB2}+R₃I₂ (5)

As I₂ is calculated by using the equations (1), (2), (4) and (5), the following equation (6) is acquired.

$${I}_{2} = \frac{1}{{R}_{3}} \frac{kT}{q} ln ( nm ) \qquad ( 6 )$$

If V_{ref} is calculated here, the following equation (7) is drawn out from the equations (1), (4) and (6).

$${V}_{ref} = {V}_{EB 1} + {R}_{1} {I}_{1} = \frac{1}{q} {E}_{g} + \frac{kT}{q} [ ln \frac{mk ln ( nm )}{{qbR}_{3}} + \frac{{mR}_{1}}{{R}_{3}} ln ( nm ) - \frac{3}{2} ln T ] \qquad ( 7 )$$

In the equation (7), m is the ratio of resistance values of R₁ and R₂, and the only item that is not expressed by a ratio is R₃ in the denominator of the LOG term. Therefore, if the first resistor R₃ varies from its designed value, it is necessary to enable fine adjustment of the resistance value of R₃ in advance, then examine the actual quantity of change, and adjust the resistance value in accordance with the quantity of change. As a result of this adjustment, a reference voltage (V_{ref}) having no influence of “apex temperature variation” and “output voltage variation” is acquired.

### Reason why Trimming of Third Resistor R₄ is not Necessary in the Case of Temperature Sensor Circuit Alone

I₁ and I₂ in FIG. 6 are calculated by the equations (4) and (6). Now, if the current mirror ratio (W/L ratio) of the transistors M₄ and M₃ is α, the following equation (8) holds.

$${I}_{PTAT} = α ( {I}_{1} + {I}_{2} ) = α \frac{m + 1}{{R}_{3}} \frac{kT}{q} ln ( nm ) \qquad ( 8 )$$

Thus, in consideration of m=R₂/R₁, the temperature sensor output (V_{PTAT}) is expressed as in the following equation (9).

$${V}_{PTAT} = α ( m + 1 ) \frac{{R}_{4}}{{R}_{3}} \frac{kT}{q} ln ( nm ) ∝ \frac{{R}_{4}}{{R}_{3}} ( \frac{{R}_{2}}{{R}_{1}} + 1 ) \frac{kT}{q} ln ( \frac{{nR}_{2}}{{R}_{1}} ) \qquad ( 9 )$$

The equation (9) is expresses by the ratio of resistances and includes no resistance that appears isolated. Therefore, in the case of the temperature sensor circuit alone, the resistance of the temperature sensor output (V_{PTAT}) does not need trimming.

However, as described above, if the temperature sensor circuit and the reference voltage generating circuit are combined, the influence of resistance trimming in the reference voltage generating circuit has influence on the temperature sensor circuit, causing the temperature sensor output to vary. Thus, in this embodiment, the first resistor R₃ and the third resistor R₄ are adjusted in the same proportion in an interlocked manner. This enables maintaining high accuracy of the outputs of the two circuits even in the case where the temperature sensor circuit and the reference voltage generating circuit are combined. The circuit of this embodiment will now be described in detail.

Detailed Description of Circuit According to this Embodiment

FIG. 7A and FIG. 7B will now be referred to. In FIG. 7A and FIG. 7B, A₁ represents an operational amplifier, R₁, R₂, R₃ and R₄ represent resistors, Q₁ and Q₂ represent pnp-type BJTs, and M₃ and M₄ represent p-type MOS-FETs. V_{ref} represents constant-voltage output, V_{PTAT} represents temperature sensor output, and V_{DD} represents power-supply voltage supplied to the circuit from outside. The output voltage V_{PTAT} of the temperature sensor is expressed by the following equation (10).

$${V}_{PTAT} ∝ \frac{{R}_{4}}{{R}_{3}} ( \frac{{R}_{2}}{{R}_{1}} + 1 ) \frac{kT}{q} ln ( \frac{{nR}_{2}}{{R}_{1}} ) \qquad ( 10 )$$

In the equation (10), a voltage proportional to absolute temperature is outputted. In the equation, k represents the Boltzmann constant, T represents absolute temperature, and q represents elementary electric charge. As described in the traditional example, adjustment of element variation is essential to restrain “apex temperature variation” and “output voltage variation” of V_{ref}. In this circuit, the resistance value of R₃ is adjusted. The problem here is the temperature sensor output. The variation characteristic of elements formed on the IC is that variation of an absolute quantity (for example, resistance value or the like) is large, whereas variation of a relative quantity (for example, resistance ratio) is smaller than the variation of the absolute quantity. As indicated in the equation (1), if the value of R₃ is changed for adjustment of element variation, the value of R₄/R₃ differs from its designed value and the characteristic of V_{PTAT} is deviated from a desired characteristic, causing the problem of “inclination variation” and “output voltage variation” of V_{PTAT}. As a measure to address this problem, the resistance value of the resistor R₄ is adjusted as well in accordance with the following equation (11).

$$Δ {R}_{4} = \frac{{R}_{4}}{{R}_{3}} Δ {R}_{3} \qquad ( 11 )$$

In the equation, ΔR₃ and ΔR₄ represent adjustment quantities for the resistors R₃ and R₄, respectively. The resistance values of R₃ and R₄ after the adjustment become R₃+ΔR₃ and R₄+ΔR₄, respectively. By adjusting As R₃ and R₄ simultaneously, it is possible to adjust the characteristic of the constant-voltage output without having influence on the characteristic of the temperature sensor output.

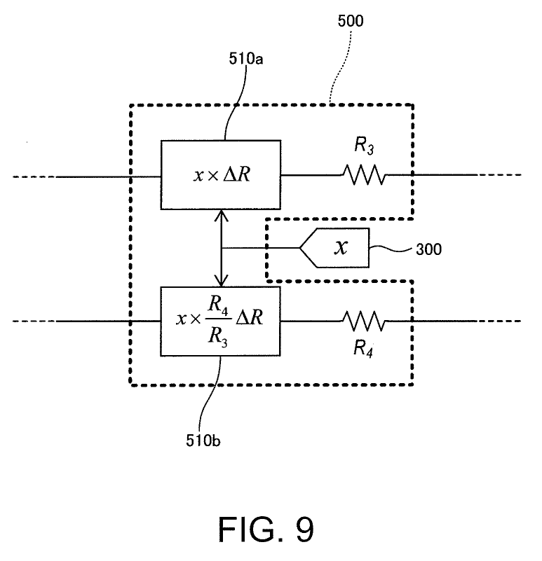

Circuits that adjust the resistance values may separately adjust the resistance of R₃ and R₄ in accordance with the equation (11) by using laser trimming, analog switches such as transistors, or non-volatile memories such as EEPROM. However, it is also possible to share the circuit that adjusts the resistance values, as shown in FIG. 7B and FIG. 9. FIG. 9 shows a fundamental configuration of a variable resistance circuit for variably adjusting the first and third resistors in an interlocked manner (an example of varying with a common trimming signal). In FIG. 9, x represents trimming quantity by the trimming circuit 300. Numerals 510a and 510b denote circuits for finely adjusting the resistor R₃ and the resistor R₄, respectively, included in the variable resistance circuit 500.

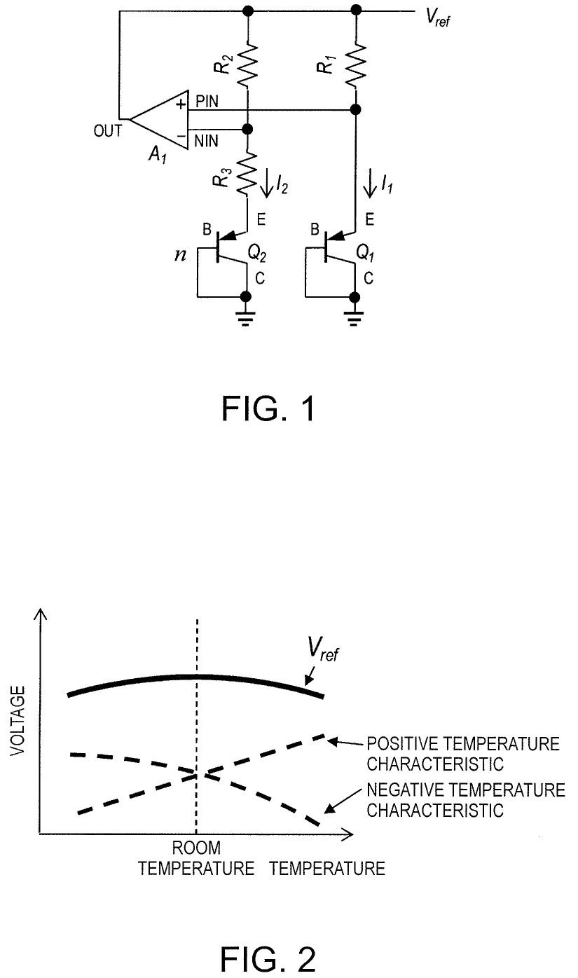

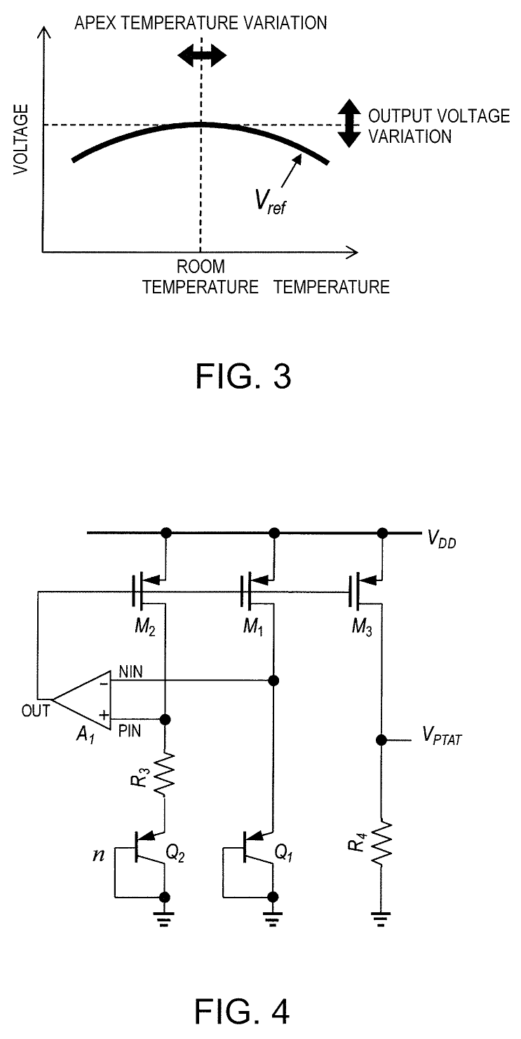

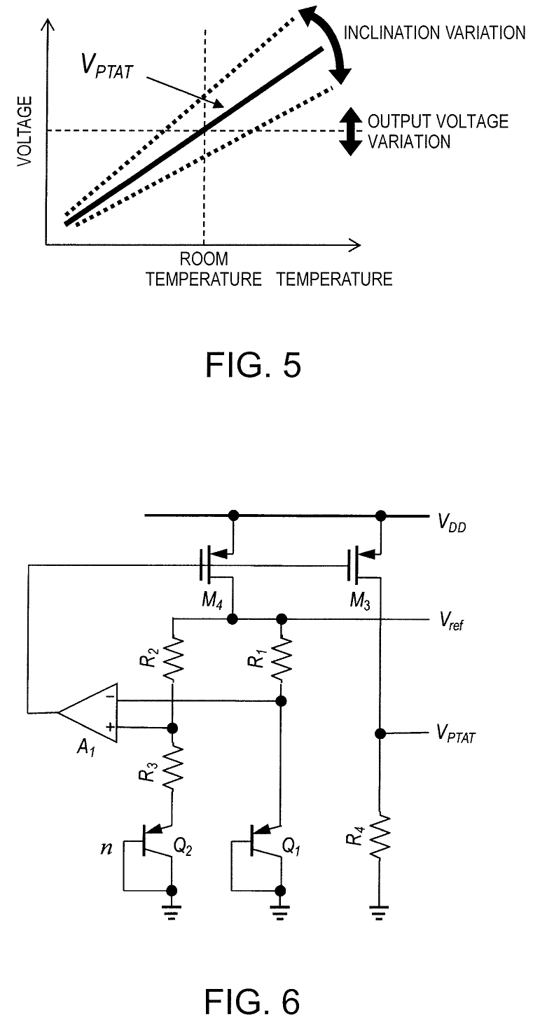

Similarly, in the circuit shown in FIG. 8 (the circuit using a current mirror instead of an operational amplifier), it is possible to trim the resistance value. In FIG. 8, R₁, R₃ and R₄ represent resistors, Q₁, Q₂ and Q₃ represent pnp-type BJTs, M₁ and M₂ represent n-type MOS-FETs, and M₃, M₄, M₅ and M₆ represent p-type MOS-FETs. V_{ref} represents constant-voltage output, V_{PTAT} represents temperature sensor output, and V_{DD} represents power-supply voltage supplied to the circuit from outside. In FIG. 7A and FIG. 7B, the inversion and non-inversion input terminals of the operation amplifier A₁ are maintained at the same potential by virtual grounding. However, in the case of FIG. 8, the current mirror circuit (M₁ to M₄) plays this role. If M₁-M₂ and M₃-M₄ use transistors of the same size to form the current mirror circuit, the same current flows through the BJTs of Q₁ and Q₂. Of course, the current mirror circuit may be formed by using transistors of difference sizes. In such a case, the ratio of currents flowing through the BJTs of Q₁ and Q₂ is constant. Here, if the same current flows through the BJTs of Q₁ and Q₂, since R₃ of FIG. 9 functions similarly to R₃ of FIG. 1 showing the traditional example, the currents I₁ and I₂ flowing through the BJTs of Q₁ and Q₂ are expressed by the following equation (12).

$${I}_{1} = {I}_{2} = \frac{kT}{q} \frac{1}{{R}_{3}} ln n \qquad ( 12 )$$

The current expressed by the equation (12) is copied by using the transistor M₅. The current is caused to flow through R₄ and converted to a voltage V_{PTAT}. That is, if the circuit of FIG. 7A and FIG. 7B according to the first embodiment is compared with the circuit of FIG. 8, it can be seen that R₃ of FIG. 8 corresponds to R₃ of FIG. 7A and FIG. 7B and that R₄ of FIG. 8 corresponds to R₄ of FIG. 7A and FIG. 7B. Therefore, adjustment of element variation is essential to restrain “apex temperature variation” and “output voltage variation” of V_{ref}. In the circuit of FIG. 8, the resistance value of R₃ is adjusted. Moreover, it can be understood that the resistance value of R₄ can be adjusted in accordance with the following equation (13) in order to prevent “inclination variation” and “output voltage variation” of V_{PTAT}.

$$Δ {R}_{4} = \frac{{R}_{4}}{{R}_{3}} Δ {R}_{3} \qquad ( 13 )$$

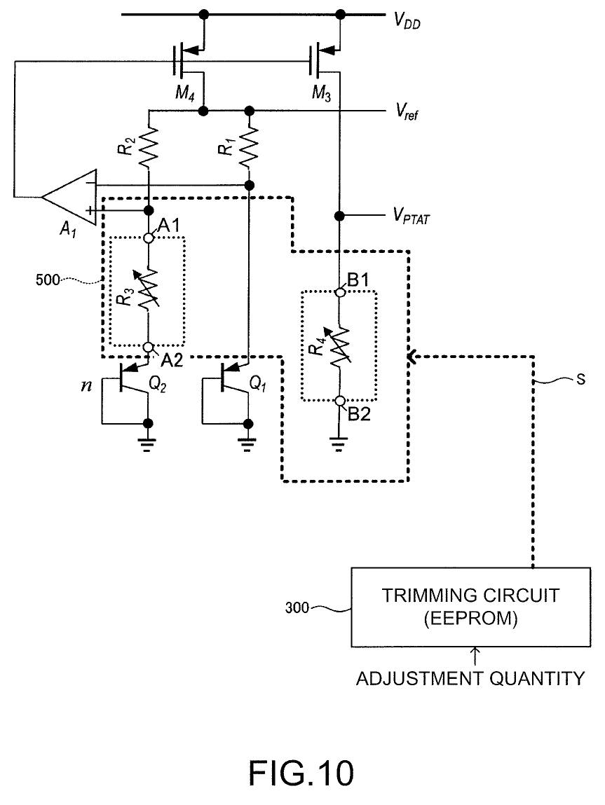

Next, a specific exemplary configuration of the variable resistance circuit 500 will be described. The variable resistance circuit 500 is a circuit for variably adjusting the resistance values of the first resistor R₃ and the third resistor R₄, as shown in FIG. 10. FIG. 10 is a circuit diagram for explaining the position where the variable resistance circuit is provided. In FIG. 10, the first resistor R₃ formed in the variable resistance circuit is provided, for example, between a first node A1 and a second node A2. The third resistor R₄ formed in the variable resistance circuit is provided between a third node B₁ and a fourth node B2.

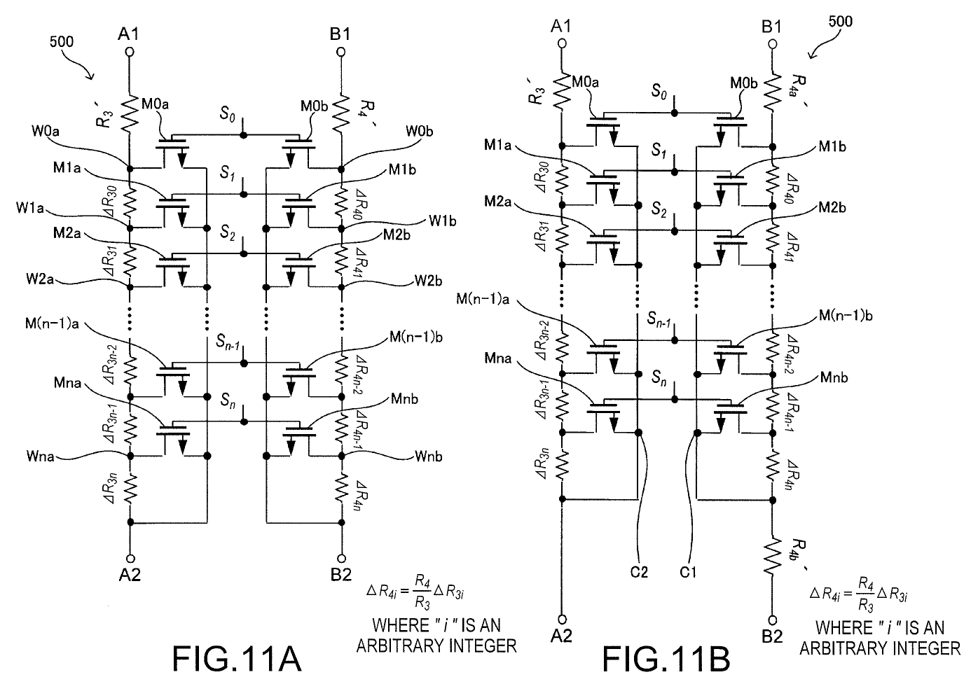

FIG. 11A and FIG. 11B are circuit diagrams showing an exemplary configuration of the variable resistance circuit. FIG. 11A will now be referred to. Between the first node A1 and the second node A2, a resistor R₃′ and resistors ΔR₃₀ to ΔR₃ₙ for fine adjustment are connected in series. The resistor R₃′ and the resistors ΔR₃₀ to ΔR₃ₙ for fine adjustment form a first ladder resistance circuit. Each of these resistors functions to divide the voltage between the first node A1 and the second node A2 and therefore can be called a voltage divider-resistor. However, the resistor R₃′ is the main resistor, and as the resistance values of the resistors ΔR₃₀ to ΔR₃ₙ for fine adjustment are added to the main resistor R₃′, the substantial resistance value of the first resistor R₃ is decided. Similarly, between the third node B1 and the fourth node B2, a resistor R₄′ and resistors ΔR₄₀ to ΔR₄ₙ for fine adjustment are connected in series. The resistor R₄′ and the resistors ΔR₄₀ to ΔR₄ₙ for fine adjustment form a second ladder resistance circuit. Each of these resistors functions to divide the voltage between the third node B1 and the fourth node B2 and therefore can be called a voltage divider-resistor. However, the resistor R₄′ is the main resistor, and as the resistance values of the resistors ΔR₄₀ to ΔR₄ₙ for fine adjustment are added to the main resistor R₄′, the substantial resistance value of the third resistor R₄ is decided. The ratio of the resistance value of each of the resistors ΔR₃₀ to ΔR₃ₙ for fine adjustment to the resistance value of the corresponding one of the resistors ΔR₄₀ to ΔR₄ₙ for fine adjustment is constant. That is, ΔRᵢ=(R₄/R₃)ΔR₃ᵢ (where 0≦i≦n) holds.

S0 to Sn represent adjustment terminals to which a common trimming signal (S) is inputted. In the case of the circuit configuration shown in FIG. 7A and FIG. 7B, a voltage that turns on MOS transistors (M0a, M0b to Mna, Mnb) is applied to only one of the adjustment terminals S0 to Sn in accordance with the adjustment quantity, and a voltage that turns off the MOS transistors is applied to all the other terminals. Thus, the resistance values of R₃ and R₄ are adjusted in the same proportion as indicated by the equation (11).

The NMOS transistors (M0a to Mna) function as bypass switches that control electric connection and disconnection between each of voltage divider nodes (W0a to Wna) of the first ladder resistance circuit and the second node A2. As one of the bypass switches turns on, the voltage divider-resistors downstream of that bypass switch are invalidated. By selecting the bypass switch to turn on, it is possible to variably adjust the substantial resistance value of the first ladder resistance circuit. Similarly, the NMOS transistors (M0b to Mnb) function as bypass switches that control electric connection and disconnection between each of voltage divider nodes (W0b to Wnb) of the second ladder resistance circuit and the fourth node B2. As one of the bypass switches turns on, the voltage divider-resistors downstream of that bypass switch are invalidated. By selecting the bypass switch to turn on, it is possible to variably adjust the substantial resistance value of the second ladder resistance circuit. As described above, the ratio of the resistance value of each of the resistors ΔR₃₀ to ΔR₃ₙ for fine adjustment to the resistance value of the corresponding one of the resistors ΔR₄₀ to ΔR₄ₙ for fine adjustment is constant. Thus, if a pair of corresponding bypass transistors is simultaneously turned on by the common trimming signal (S), the resistance value of the first ladder resistance circuit and the resistance value of the second ladder resistance circuit change in the same proportion.

FIG. 11B shows a modification (improved version) of the circuit configuration of the variable resistance circuit 500. In FIG. 11B, R₄′ in the basic circuit shown in FIG. 11A is divided into R₄ₐ′ and R_{4b}′ (R₄′=R₄ₐ′+R_{4b}′). The proportion of division into R₄ₐ′ and R_{4b}′ is designed in such a manner that all the MOS-FETs connected to the adjustment terminals have the same source potential. That is, the potential adjustment resistor R_{4b}′ is provided between the most downstream voltage divider-resistor ΔR₄ₙ and the fourth node B2. As the voltage between both ends of this potential adjustment resistor R_{4b}′ is adjusted, the source potential (C1 in FIG. 11B) of the MOS transistor constituting the bypass switch is adjusted to become equal to the source potential (C2 in FIG. 11B) of the corresponding MOS transistor. Therefore, on-resistance of the bypass switch included in the second ladder resistance circuit can be adjusted to be equal to on-resistance of the corresponding bypass switch included in the first ladder resistance circuit. Thus, the accuracy of the ratio of the first ladder resistance circuit and the second ladder resistance circuit is improved. That is, on-resistance of the MOS transistor is expressed by the following equation (14).

$${R}_{on} ≅ {[ \frac{W}{L} μ {C}_{ox} ( {V}_{GS} - {V}_{T} ) ]}^{- 1} \qquad ( 14 )$$

Thus, as the MOS-FET size is designed in such a manner that the ratio of W/L of the MOS-FET on the A1-A2 side and W/L of the MOS-FET on the B1-B2 side becomes equal to the ratio of 1/R₃ and 1/R₄, the accuracy of the ratio of the resistance value between A1 and A2 and the resistance value between B1 and B2.

### Second Embodiment

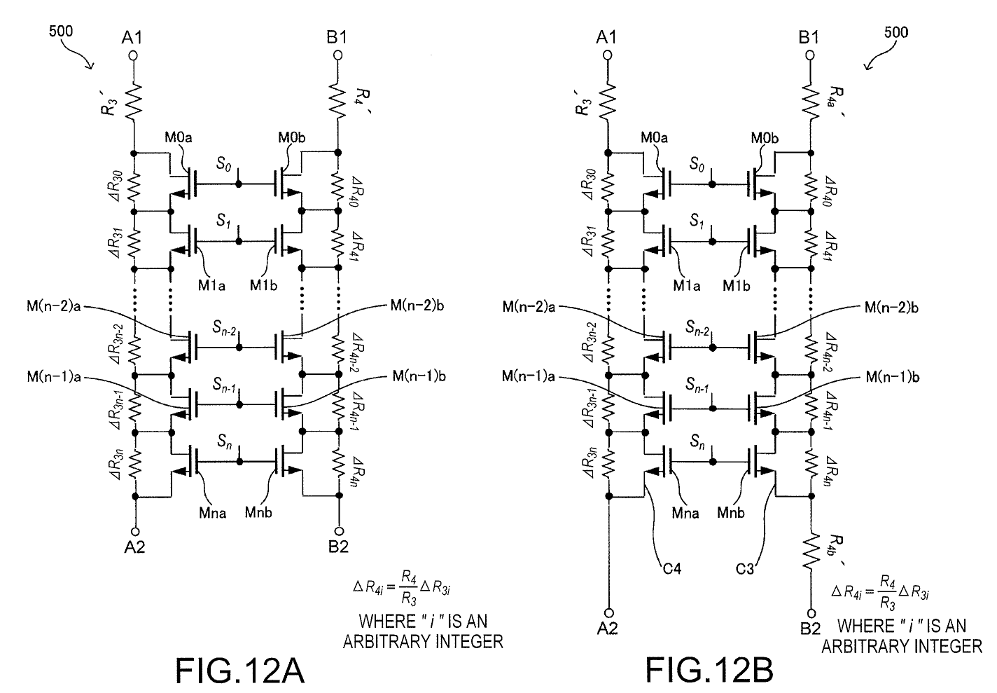

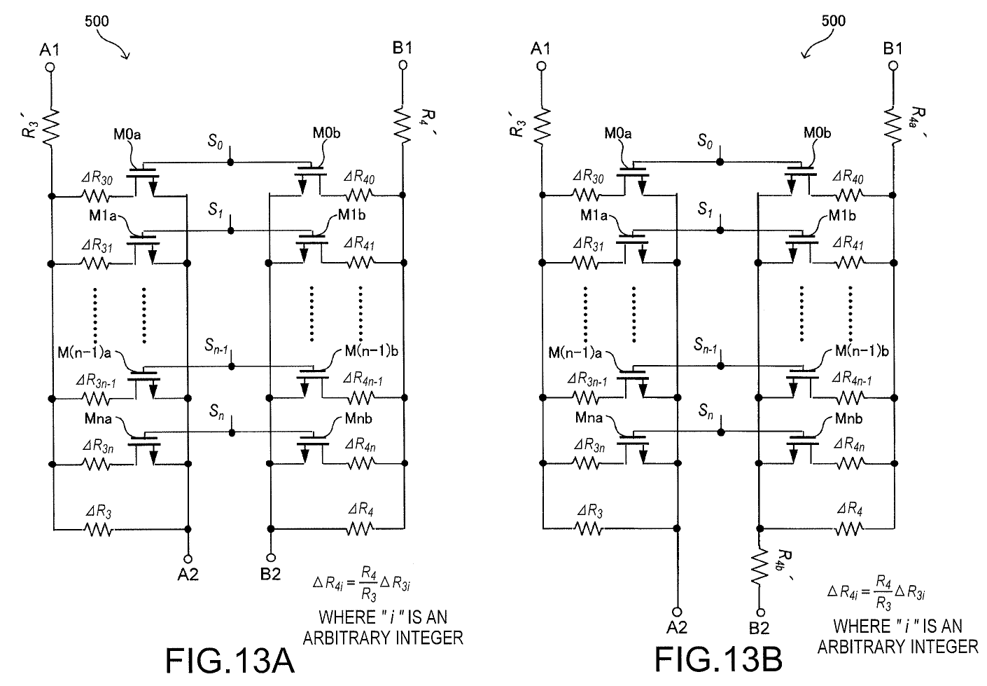

In this embodiment, another configuration of the variable resistance circuit 500 will be described. FIG. 12A and FIG. 12B are circuit diagram showing another exemplary configuration of the variable resistance circuit. In FIG. 12A and FIG. 12B, S0 to Sn represent adjustment terminals. These adjustment terminals have a difference bypass switch configuration (a different method for inputting a signal indicating the adjustment quantity) from those in FIG. 11A and FIG. 11B. In FIG. 12A and FIG. 12B, bypass switches are provided corresponding to each of the resistors ΔR₃₀ to ΔR₃ₙ for fine adjustment and the resistors ΔR₄₀ to ΔR₄ₙ for fine adjustment. As one bypass switch turns on, both ends of the corresponding resistor for fine adjustment become short-circuited and only that resistor for fine adjustment is invalidated.

In FIG. 11A and FIG. 11B, it is necessary to set one of the terminals to H and the other terminals to L. As adjustment patterns, if there are N adjustment terminals, adjustment can be made only in N stages. On the other hand, in the case of FIG. 12A and FIG. 12B, if there are N adjustment terminals, 2^{N} stages of adjustment patterns exist. For example, if S0, S2 and S3 are at L and S1, S4, S5, . . . , Sn are at H, the resistance between A1 and A2 is adjusted to R₃′+ΔR₃₀+ΔR₃₂+ΔR₃₃ and the resistance between B1 and B2 is adjusted to R₄′+ΔR₄₀+ΔR₄₂+ΔR₄₃. FIG. 12B shows a modification (improved version). The improved feature is similar to the case of FIG. 11B. That is, as the potential adjustment resistor R_{4b}′ is provided between the most downstream voltage divider-resistor ΔR₄ₙ and the fourth node B2 and the voltage between both ends of this potential adjustment resistor R_{4b}′ is adjusted, the source potential (C3 in FIG. 12B) of the MOS transistor constituting the most downstream bypass switch is adjusted to become equal to the source potential (C4 in FIG. 12B) of the corresponding MOS transistor. Therefore, on-resistance of each of the bypass switches included in the second ladder resistance circuit can be adjusted to become equal to on-resistance of the corresponding one of the bypass switches included in the first ladder resistance circuit. Thus, the accuracy of the ratio of the first ladder resistance circuit and the second ladder resistance circuit is improved.

### Third Embodiment

In this embodiment, still another exemplary configuration of the variable resistance circuit 500 will be explained. FIG. 13A and FIG. 13B are circuit diagram showing still another exemplary configuration of the variable resistance circuit. In FIG. 13A and FIG. 13B, S0 to Sn represent adjustment terminals. In FIG. 13A and FIG. 13B, adjustment resistors (ΔR₃₀ to ΔR₃ₙ, and ΔR₄₀ to ΔR₄ₙ) are connected in parallel. Switch circuits (M0a to Mna, and M0b to Mnb) are provided for the adjustment resistors (ΔR₃₀ to ΔR₃ₙ, and ΔR₄₀ to ΔR₄ₙ), respectively. One ends of the switch circuits (M0a to Mna, and M0b to Mnb) are connected to the adjustment resistors (ΔR₃₀ to ΔR₃ₙ, and ΔR₄₀ to ΔR₄ₙ), respectively. The other ends are connected in common. In FIG. 13A, the common connection points of the switch circuits (M0a to Mna) are connected to the second node A2, and the common connection points of the switch circuits (M0b to Mnb) are connected to the fourth node B2. Only when a switch circuit is turned on, the corresponding adjustment resistor is validated. By selecting which switch circuit to turn on, it is possible to variably adjust the resistance value between A1 and A2 and the resistance value between B1 and B2.

As an example, if S0, S2 and S3 are at L and S1, S4, S5, . . . Sn are at H, the resistance between A1 and A2 becomes as follows. That is, the resistance is R₃′+(ΔR₃₀∥AR₃₂∥ΔR₃₃∥ΔR₃).

The resistance between B1 and B2 is adjusted to R₄′+(ΔR₄₀∥ΔR₄₂∥ΔR₄₃∥ΔR₄). The symbol “∥” indicates parallel connection. C=A∥B has the same meaning as C⁻¹=A⁻¹+B⁻¹. In FIG. 13B, the potential adjustment resistor R_{4b}′ is connected between the common connection point of each switch circuit and the fourth node B2. As the voltage between both ends of the potential adjustment resistor R_{4b}′ is adjusted, on-resistances of the corresponding bypass switches can be adjusted to the same resistance.

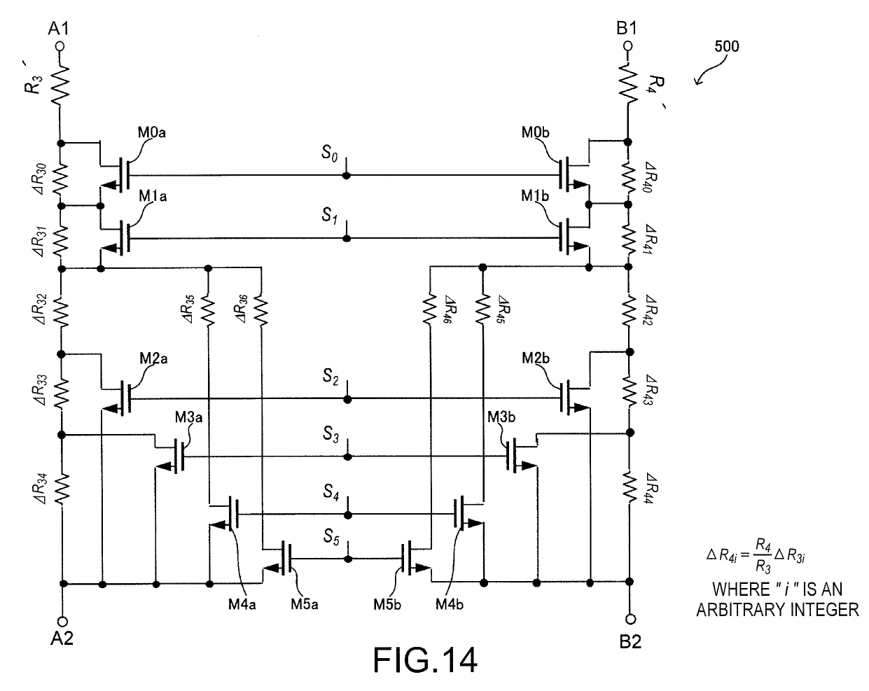

The above-described circuit configurations can also be combined. That is, some or all of the configurations of the variable resistance circuit according to the first, second and third embodiments can be combined to form a trimming circuit. There are a number of combination patterns, one of which is shown in FIG. 14. FIG. 14 shows still another exemplary circuit configuration of the variable resistance circuit. The circuits used in the foregoing description are examples and can be modified in various manners. For example, in the circuit shown in FIG. 11A and FIG. 11B, a bypass switch may be provided at intervals of two or three voltage divider-node, instead of providing a bypass switch for each voltage divider-node. In this way, modifications can be made freely.

### Fourth Embodiment

The generated highly accurate reference voltage can be used, for example, as various reference voltages in an electronic circuit or as a DC bias voltage for a signal line. The temperature sensor output can be used, for example, to generate a temperature compensation signal. It is also possible to use both the reference voltage and the temperature sensor output to generate a constant current having very little dependence on temperature (that is, a constant current that is not dependent on temperature). In this embodiment, an exemplary circuit in the case of using both the reference voltage and the temperature sensor output to generate a constant current having very little dependence on temperature will be described.

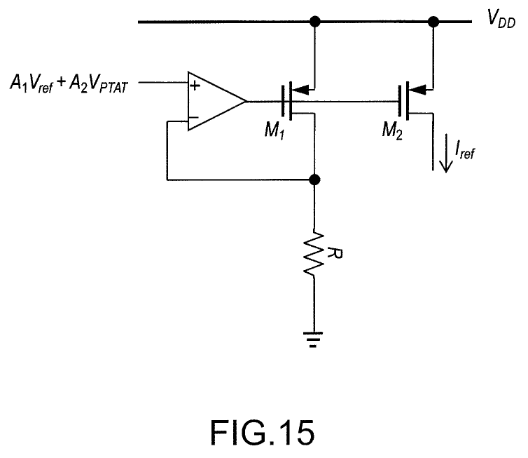

FIG. 15 shows a constant current source circuit. This circuit generates a constant current by using the temperature characteristic of V_{PTAT} and the temperature characteristic of the resistor. A voltage formed by adding the reference voltage V_{ref} multiplied by A₁ to V_{PTAT} multiplied by A₂ is inputted to the non-inversion input terminal of the operational amplifier. The current I flowing through the resistor R is expressed by the following equation (15) in consideration of the fact that non-inversion input and the inversion input of the operational amplifier have the same potential.

$$I = \frac{{A}_{1} {V}_{ref} + {A}_{2} {V}_{PTAT}}{R} \qquad ( 15 )$$

Here, the resistor R has a temperature characteristic that is expressed by the following equation (16).

R=R₀[1+C_{R}(T−T₀)] (16)

In this equation, Rₒ represents resistance value for T=Tₒ, and CR represents temperature coefficient. This CR is decided in accordance with what material and condition are used for preparing the resistor. Now, where V_{ref} represents a constant voltage irrespective of temperature and V_{PTAT} represents a voltage proportional to absolute temperature T, the following equation (17) holds.

A₁V_{ref}+A₂V_{PTAT}=a₁+a₂T (17)

In the equation, a₁ and a₂ are constant numbers. From the equations (12) and (13), it can be understood that since the denominator and numerator in the equation (11) are linear functions of T and the values of a₁ and a₂ can be designed by selecting appropriate A₁ and A₂, a current having very little dependence on temperature can be generated. The transistors M₁ and M₂ play the role of copying the current following through the resistor R, thus enabling output of a constant current I_{ref} having very little dependence on temperature. In this way, if the constant voltage source circuit and the temperature sensor circuit are provided, a constant current source circuit can be configured.

As described above, some embodiments of the invention have, for example, the following advantages. That is, in the circuit configuration formed by a combination of the reference voltage generating circuit and the temperature sensor circuit, when finely adjusting the resistance value of an appropriate resistor in the circuit in order to restrain “apex temperature variation” and “output voltage variation” of V_{ref} due to element variation, if the resistance value of an appropriate resistor on the temperature sensor circuit side is finely adjusted simultaneously in the same proportion, variation on both sides, that is, “apex temperature variation” and “output voltage variation” of V_{ref} and “inclination variation” and “output voltage variation” of V_{PTAT}, can be restrained.

Adjusting the resistance values of the two resistors simultaneously in the same proportion also has advantages that the circuit necessary for adjustment of the resistance values can be shared and that the circuit area can be reduced. Moreover, since the reference voltage generating circuit and the temperature sensor circuit can be adjusted simultaneously, adjustment cost can be reduced, compared to the case of separately adjusting the individual circuits.

### Fifth Embodiment

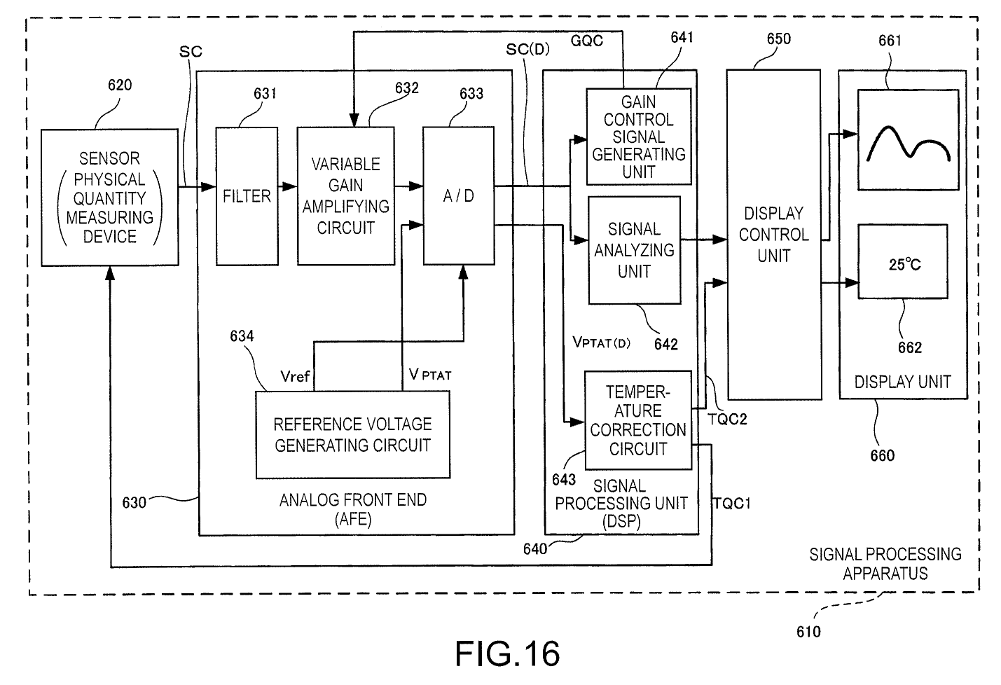

In this embodiment, an exemplary signal processing apparatus using the reference voltage generating circuit according to the invention will be described. FIG. 16 shows an exemplary configuration of the signal processing apparatus using the reference voltage generating circuit according to the invention.

A signal processing apparatus 610 has an analog front end (AFE) 630 to which an output signal SC of a sensor (physical quantity measuring device) 620 is inputted, a signal processing unit (for example, a digital signal processor or DSP) 640, a display control unit 650, and a display unit 660. The sensor (physical quantity measuring device) 620 is, for example, a motion sensor that detects motion and attitude of an object. More specifically, the sensor 620 is, for example, a gyro sensor. If the sensor 620 is a gyro sensor, the output signal SC is an angular velocity signal. The signal processing unit 640 has a gain control signal generating unit 641, a signal analyzing unit 642, and a temperature correction circuit 643 as a temperature signal processing unit. The analog front end (AFE) 630 has a filter circuit 631, a variable gain amplifying circuit 632 as a gain adjustment circuit, an A/D converter 633, and a reference voltage generating circuit 634 that is one of the reference voltage generating circuits described in the above embodiments. The display unit 660 has a waveform display unit (waveform display window) 661, and a temperature display unit (temperature display window) 662. The display control unit 650 controls image display in the display unit 660.

The analog front end (AFE) 630 performs predetermined analog signal processing (for example, filtering, variable gain amplification, A/D conversion or the like) to the inputted analog signal SC. The analog front end (AFE) 630 is provided with the reference voltage generating circuit 634 according to the invention. The reference voltage generating circuit 634 can output a reference voltage V_{ref} that is influenced very little by temperature, and therefore can be used as a reference voltage source or power voltage source for at least one circuit included in the analog front end (AFE).

The reference voltage generating circuit 634 can also output a temperature-dependent voltage V_{PTAT} and therefore can also play the role of a temperature sensor that measures ambient temperature around the analog front end (AFE) 630. It is also possible to execute temperature characteristic correction to correct the temperature characteristic of the circuit in accordance with the temperature-dependent signal V_{PTAT}.

In FIG. 16, the reference voltage V_{ref} generated by the reference voltage generating circuit 634 is supplied to the A/D converter 633, for example, as a reference for generating a gradationally controlled voltage. Thus, the characteristic of the A/D converter 633 is stabilized with respect to temperature and highly accurate A/D conversion that is little influenced by temperature is realized.

The analog signal SC inputted from the sensor 620 is converted to a digital signal SC(D) by the A/D converter 633. The digital signal SC(D) is supplied to the signal processing unit (DSP) 640. The temperature-dependent voltage V_{PTAT} outputted from the reference voltage generating circuit 634 is converted to a digital signal V_{PTAT(D)} by the A/D converter 633. The digital signal V_{PTAT(D)} is sent to the signal processing unit (DSP) 640.

The signal processing unit (for example, DSP) 640 executes signal processing (analog signal processing), for example, signal analysis, generation of a gain control signal, and generation of a temperature correction signal. Since the circuit characteristic of the analog front end (AFE) 630 is stable with respect to temperature, the signal processing apparatus 610 can execute highly accurate signal processing without being influence by temperature.

The gain control signal generating unit 641 provided in the signal processing unit (for example, DSP) 640 generates a gain control signal GQC in accordance with the above digital signal SC(D). By this gain control signal GQC, the gain of the variable gain amplifier 632 as the gain adjustment circuit is adjusted. For example, the gain of the variable gain amplifier 632 is adjusted in such a manner that the amplitude of the output signal of the variable gain amplifying circuit 632 becomes constant.

The signal analyzing unit 642 executes predetermined analysis based on the digital signal SC(D) and acquires, for example, information about change in amplitude and frequency of the signal on the time axis. The result of the signal analysis is sent from the signal analyzing unit 642 to the display control unit 650.

The temperature correction circuit 643 as the temperature signal processing unit generates a temperature correction signal TQC1 based on the above digital signal V_{PTAT(D)}. The temperature correction signal TQC1 is supplied to the sensor (physical quantity measuring device) 620. Thus, the temperature characteristic of the output signal SC of the sensor (physical quantity measuring device) 620 is canceled. The temperature correction circuit 643 also acquires information TQC2 about change in temperature on the temperature time axis. The acquired temperature information TQC2 is sent from the temperature correction circuit 643 to the display control unit 650.

The display control unit 650 controls image display in the display unit 660. As described above, the display unit 660 has the waveform display unit (waveform display window) 661 and the temperature display unit (temperature display window) 662. In the waveform display unit (waveform display window) 661, for example, the signal waveform of the analog signal SC outputted from the sensor 620 is displayed. In the temperature display unit (temperature display window) 662, for example, temperature (for example, 25° C.) is digitally displayed.

According to this embodiment, a signal processing apparatus, for example, a sensor signal processing apparatus (sensor signal processing system) capable of executing constantly stable processing and highly accurate processing without being influenced by ambient temperature can be realized.

Although the embodiments are described above in detail, those skilled in the art can easily understand that various modifications can be made without departing from the scope of the invention. Therefore, all such modifications should be included in the invention.

The invention has an advantage that both generation of a highly accurate reference voltage having very little dependence on temperature (that is, a reference voltage that is not dependent on temperature) and a highly accurate temperature sensor output voltage can be realized. Therefore, the invention can preferably be applied to the entire range of analog semiconductor integrated circuits, particularly, to integrated circuit devices that need temperature correction, for example, a reference voltage generating circuit (a reference voltage generating circuit that outputs a reference voltage and a temperature-dependent voltage in parallel), and an integrated circuit device having this reference voltage generating circuit and a trimming circuit.

The entire disclosure of Japanese Patent Application Nos. 2008-030043, filed Feb. 12, 2008 and 2008-297731, filed Nov. 21, 2008 are expressly incorporated by reference herein.

What is claimed is:

1. A reference voltage generating circuit comprising:
a first pn junction that generates a first voltage;
a second pn junction that has a different current density from the first pn junction;
a first resistor that generates a first current having a positive temperature coefficient based on a voltage equivalent to a difference between a forward voltage of the first pn junction and a forward voltage of the second pn junction;
a second resistor that generates a first voltage having a positive temperature coefficient based on the first current, wherein the first voltage having the positive temperature coefficient and a voltage having a negative temperature coefficient are added to generate the reference voltage; and
a third resistor that generates a temperature-dependent voltage based on the first current having the positive temperature coefficient, wherein the reference voltage and the temperature-dependent voltage are outputted in parallel from first and second output nodes, respectively; and
wherein a resistance value of the first resistor and a resistance value of the third resistor are adjusted in the same proportion by a trimming signal.

2. The reference voltage generating circuit according to claim 1, wherein the first resistor and the third resistor include a variable resistance circuit in which the first and third resistors have their respective resistance values adjusted in the same proportion in accordance with the trimming signal that is common.

3. The reference voltage generating circuit according to claim 2, wherein the variable resistance circuit comprises:
a first ladder resistance circuit including first to m-th (m being an integer equal to 2 or greater) voltage divider-resistors connected in series between a first node and a second node for variably adjusting the resistance value of the first resistor;
a second ladder resistance circuit including first to m-th voltage divider-resistors connected in series between a third node and a fourth node for variably adjusting the resistance value of the third resistor;
first to i-th bypass switches for the first ladder resistance circuit for switching electric connection and disconnection between each of first to i-th (i being an integer equal to 2 or greater) division nodes and the second node in the first ladder resistance circuit; and
first to i-th bypass switches for the second ladder resistance circuit for switching electric connection and disconnection between each of first to i-th (i being an integer equal to 2 or greater) division nodes and the fourth node in the second ladder resistance circuit;
wherein a ratio of a resistance value of an n-th voltage divider-resistor (1≦n≦m) forming the first ladder resistance circuit to a resistance value of an n-th voltage divider-resistor (1≦n≦m) forming the second ladder resistance circuit is constant; and
on-off state of a k-th bypass switch (1≦k≦i) for the first ladder resistance circuit and on-off state of a k-th bypass switch (1≦k≦i) for the second ladder resistance circuit are controlled by the common trimming signal.

4. The reference voltage generating circuit according to claim 2, wherein the variable resistance circuit comprises:
a first ladder resistance circuit including first to m-th (m being an integer equal to 2 or greater) voltage divider-resistors connected in series between a first node and a second node for variably adjusting the resistance value of the first resistor;
a second ladder resistance circuit including first to m-th voltage divider-resistors connected in series between a third node and a fourth node for variably adjusting the resistance value of the third resistor;
first to m-th bypass switches for the first ladder resistance circuit provided corresponding to each of the first to m-th voltage divider-resistors forming the first ladder resistance circuit and for bypassing both ends of each of the first to m-th voltage divider-resistors; and
first to m-th bypass switches for the second ladder resistance circuit provided corresponding to each of the first to m-th voltage divider-resistors forming the second ladder resistance circuit and for bypassing both ends of each of the first to m-th voltage divider-resistors;
wherein a ratio of a resistance value of an n-th voltage divider-resistor (1≦n≦m) forming the first ladder resistance circuit to a resistance value of an n-th voltage divider-resistor (1≦n≦m) forming the second ladder resistance circuit is constant, and
on-off state of a p-th bypass switch (1≦p≦m) for the first ladder resistance circuit and on-off state of a p-th bypass switch (1≦p≦m) for the second ladder resistance circuit are controlled by the common trimming signal.

5. The reference voltage generating circuit according to claim 3, wherein a potential adjustment resistor for adjusting potential of a node on the fourth node side, of the m-th voltage divider-resistor in the second ladder resistance circuit, is provided between the m-th voltage divider-resistor and the fourth node.

6. The reference voltage generating circuit according to claim 2, wherein the variable resistance circuit comprises:
first to q-th (q being an integer equal to 2 or greater) resistors for adjustment of the first resistor, connected parallel to each other between the first node and the second node and having their one ends connected in common, for variably adjusting the resistance value of the first resistor;
first to q-th resistors for adjustment of the third resistor, connected parallel to each other between the third node and the fourth node and having their one ends connected in common, for variably adjusting the resistance value of the third resistor;
first to q-th switch circuits for adjustment of the first resistor, provided corresponding to each of the first to q-th resistors for adjustment of the first resistor, for switching electric connection and disconnection between the other end of each of the first to q-th resistors for adjustment of the first resistor and the second node; and
first to q-th switch circuits for adjustment of the third resistor, provided corresponding to each of the first to q-th resistors for adjustment of the third resistor, for switching electric connection and disconnection between the other end of each of the first to q-th resistors for adjustment of the third resistor and the fourth node;
wherein a resistance ratio of a resistance value of an r-th (1≦r≦q) resistor for adjustment of the first resistor to a resistance value of an r-th (1≦r≦q) resistor for adjustment of the third resistor is constant; and
on-off state of an x-th switch circuit (1≦x≦q) for adjustment of the first resistor and on-off state of an x-th switch circuit (1≦x≦q) for adjustment of the third resistor are controlled by the common trimming signal.

7. The reference voltage generating circuit according to claim 6, wherein one ends of the first to q-th switch circuits for adjustment of the third resistor are connected to the other ends of the first to q-th resistors for adjustment of the first resistor, and the other ends of the first to q-th switch circuits for adjustment of the third resistor are connected in common, and
a potential adjustment resistor for adjusting potential of each common connection point of the first to q-th switch circuits for adjustment of the third resistor is provided between each common connection point of the first to q-th switch circuits and the fourth node.

8. An integrated circuit device comprising:
the reference voltage generating circuit according to claim 1; and
a trimming circuit that outputs the trimming signal.

9. A signal processing apparatus comprising:
an analog front end that includes the reference voltage generating circuit according to claim 1 and caries out analog signal processing to an analog signal that is inputted thereto; and
a signal processing unit that executes predetermined signal processing based on an output signal of the analog front end.

10. The signal processing apparatus according to claim 9, wherein the analog front end has an analog-digital (A/D) converter that converts an analog signal to a digital signal,
the reference voltage outputted form the reference voltage generating circuit is supplied to the A/D converter, and
the temperature-dependent voltage outputted from the reference voltage generating circuit is converted to a digital signal by the A/D converter, and the digital signal after the conversion is inputted to the signal processing unit.

11. The signal processing apparatus according to claim 10, wherein the analog front end has at least one of a filter circuit and a gain adjusting circuit before the A/D converter, and a sensor signal outputted from a sensor is inputted to the analog front end, and
the signal processing unit has a temperature signal processing unit that execute temperature signal processing based on the temperature-dependent voltage as the digital signal, outputted from the A/D converter.
